(19) United States
(12) Patent Application Publication
(10) Pub. No.: US 2025/0331185 A1
(43) Pub. Date: Oct. 23, 2025

(54) SEMICODUCTOR DEVICE INCLUDING A DECOUPLING CAPACITOR

(71) Applicant: SK hynix Inc., Icheon-si Gyeonggi-do (KR)

(72) Inventors: Beom Kyu SEO, Icheon-si Gyeonggi-do (KR); Bon Kwang KOO, Icheon-si Gyeonggi-do (KR); Soon Sung AN, Icheon-si Gyeonggi-do (KR); Sung Hwa OK, Icheon-si Gyeonggi-do (KR); Jun Seo JANG, Icheon-si Gyeonggi-do (KR); Eun Ji CHOI, Icheon-si Gyeonggi-do (KR); Jae Hyeong HONG, Icheon-si Gyeonggi-do (KR)

(73) Assignee: SK hynix Inc., Icheon-si Gyeonggi-do (KR)

(21) Appl. No.: 18/825,842

(22) Filed: Sep. 5, 2024

(30) Foreign Application Priority Data
Apr. 18, 2024 (KR) 10-2024-0052052

(51) Int. Cl. H10B 43/40; H10B 43/27

(52) U.S. Cl. CPC H10B 43/40; H10B 43/27

(57) ABSTRACT

Embodiments of the present disclosure are related to a semiconductor device including a substrate; at least one lower interconnection layer disposed on a substrate; a first upper interconnection layer on the at least one lower interconnection layer; a second upper interconnection layer on the first upper interconnection layer; an external connection pad, the second upper interconnection layer including the external connection pad; and a metal oxide semiconductor (MOS) capacitor disposed on said substrate vertically overlapping with the external connection pad, wherein the at least one lower interconnection layer including a main decoupling capacitor region vertically overlapping with the MOS capacitor; and additional decoupling capacitor region surrounding the main decoupling capacitor region.

### CROSS-REFERENCE TO RELATED APPLICATION

The present application claims priority under 35 U.S.C. § 119 (a) to Korean Patent Application No. 10-2024-0052052 filed in the Korean Intellectual Property Office on Apr. 18, 2024, which application is incorporated herein by reference in its entirety.

### BACKGROUND

### 1. Technical Field

The present disclosure generally relates to semiconductor technology, and more particularly, to a semiconductor device including a decoupling capacitor.

### 2. Related Art

With the increasing integration of semiconductor devices, there is a growing need for increased storage capacity, as well as a need for increased speed of operation. Read and write operations introduce transient noise into the power supply voltage, and as the speed of operation increases, semiconductor devices can become very susceptible to noise. To filter noise in the power supply voltage, the semiconductor device has a decoupling capacitor connected between the power supply voltage and the ground voltage.

### SUMMARY

Embodiments of the present disclosure can provide a semiconductor device including a substrate at least one lower interconnection layer disposed on the substrate; a first upper interconnection layer on the at least one of the lower interconnection layer; a second upper interconnection layer on the first upper interconnection layer; an external connection pad, the second upper interconnection layer including the external connection pad; and a metal oxide semiconductor (MOS) capacitor disposed on the substrate to be vertically overlapping with the external connection pad, wherein the at least one of the lower interconnection layer including a main decoupling capacitor region vertically overlapping with the MOS capacitor; and an additional decoupling capacitor region surrounding the main decoupling capacitor region.

Embodiments of the present disclosure can provide a semiconductor device including a peripheral structure including a substrate having a first region and a second region defined thereon, circuit devices disposed on the substrate, and a lower interconnection layer disposed on the circuit devices; a cell structure including a memory cell array disposed on the second region of the peripheral structure, a first upper interconnection layer on the memory cell array, a second upper interconnection layer on the first upper interconnection layer, and an external connection pad disposed in the first region and the second upper interconnection layer including the external connection pad; a first vertical via and a second vertical via vertically overlapping with the external connection pad and extending vertically between the lower interconnection layer and the first upper interconnection layer; and a first decoupling capacitor including the first vertical via, the second vertical via, and a dielectric layer between the first vertical via and the second vertical via.

Embodiments of the present disclosure can provide a semiconductor device including: a peripheral structure including a substrate having a first region and a second region defined thereon, a metal oxide semiconductor (MOS) capacitor disposed on the first region of the substrate, a lower dielectric layer covering the MOS capacitor, and a lower interconnection layer disposed on the lower dielectric layer; a cell structure including a source plate disposed on the second region of the peripheral structure, a gate laminate including a plurality of gate electrode layers and a plurality of interlayer insulating layers alternately stacked on the source plate, a first upper dielectric layer covering the source plate and the gate laminate, a second upper dielectric layer on the first upper dielectric layer, a first upper interconnection layer on the second upper dielectric layer, a third upper dielectric layer covering the first upper interconnection layer, a second upper interconnection layer on the third upper dielectric layer, and an external connection pad disposed on the first region, the external connection pad included in the second upper interconnection layer; a first vertical via and a second vertical via vertically overlapping with the external connection pad and vertically penetrating the first upper dielectric layer; and a first decoupling capacitor including the first vertical via, the second vertical via, and the first upper dielectric layer between the first vertical via and the second vertical via.

### BRIEF DESCRIPTION OF THE DRAWINGS

FIG. 1 is a cross-sectional view of a semiconductor device according to various embodiments of the present disclosure.

FIG. 2 is a plan view illustrating an embodiment of the main decoupling capacitor region and the additional decoupling capacitor region of the first lower interconnection layer of FIG. 1.

FIG. 3 to FIG. 5 are cross-sectional views of semiconductor devices according to various embodiments of the present disclosure.

### DETAILED DESCRIPTION

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present disclosure, detailed descriptions of well-known functions and components incorporated herein will be omitted when it is determined that the description may make the subject matter in some embodiments of the present disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the present disclosure. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other. It will be understood that when an element or layer etc., is referred to as being “on,” “connected to” or “coupled to” another element or layer etc., it can be directly on, connected or coupled to the other element or layer etc., or intervening elements or layers etc., may be present. In contrast, when an element or layer etc., is referred to as being “directly on,” “directly connected to” or “directly coupled to” another element or layer etc., there are no intervening elements or layers etc., present. Like numerals refer to like elements throughout.

When time relative terms, such as “after”, “subsequent to”, “next”, “before” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Various embodiments of the present disclosure will be described in detail below with reference to the accompanying drawings.

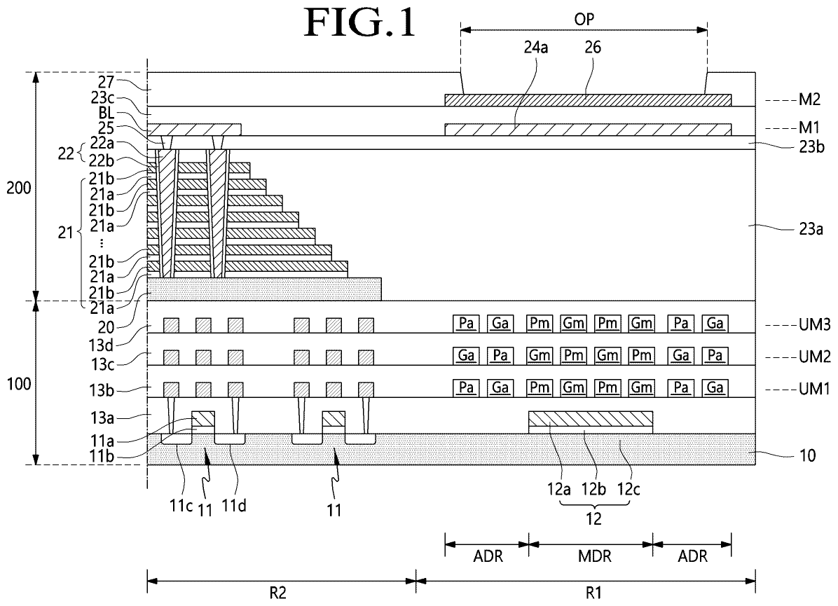

FIG. 1 is a cross-sectional view of a semiconductor device according to various embodiments of the present disclosure.

Referring to FIG. 1, a semiconductor device according to various embodiments of the present disclosure may include a lower structure 100, and an upper structure 200 disposed on the lower structure 100.

The upper structure 200 may include a first external connection pad 26. The semiconductor device may include a first region R1 and a second region R2. The first external connection pad 26 may be disposed in the first region R1. In one embodiment, the first external connection pad 26 may be a power pad. In another embodiment, the first external connection pad 26 may be a ground pad. Although not shown, the upper structure 200 further includes a plurality of second external connection pads. The second external connection pads may include at least one of, for example, a data pad, an address pad, a command pad, and a control signal pad.

The lower structure 100 may include a MOS capacitor 12 vertically overlapping with the first external connection pad 26. The lower structure 100 may include at least one lower interconnection layer. The at least one lower interconnection layer may include, for example, a first lower interconnection layer UM1, a second lower interconnection layer UM2, and a third lower interconnection layer UM3.

The first region R1 may include a main decoupling capacitor region MDR and an additional decoupling capacitor region ADR vertically overlapping with the first external connection pad 26. The main decoupling capacitor region MDR may be vertically overlapping with the MOS capacitor 12, and the additional decoupling capacitor region ADR may be vertically non-overlapping with the MOS capacitor 12 or might not be vertically overlapping with the MOS capacitor 12. In an embodiment, the main decoupling capacitor region MDR may be vertically overlapping with the MOS capacitor 12, and the additional decoupling capacitor region ADR may be vertically non-overlapping with the MOS capacitor 12 or might not be vertically overlapping with the MOS capacitor 12 as shown in FIG. 1. The main decoupling capacitor region MDR may be vertically overlapping with the central region of the first external connection pad 26, and the additional decoupling capacitor region ADR may be vertically overlapping with an edge region of the first external connection pad 26. In an embodiment, the main decoupling capacitor region MDR may be vertically overlapping with the central region of the first external connection pad 26 and not an edge region of the first external connection pad 26, and the additional decoupling capacitor region ADR may be vertically overlapping with the edge region of the first external connection pad 26 and not the central region of the first external connection pad 26.

In one embodiment, the upper structure 200 may include a memory cell array, and the lower structure 100 may include peripheral circuitry that controls the operation of the memory cell array. In such a case, the lower structure 100 may be defined as a peripheral structure and the upper structure 200 may be defined as a cell structure.

For example, the lower structure 100 may include a substrate 10, circuit devices 11, a MOS capacitor 12, lower dielectric layers 13a, 13b, 13c, 13d, and lower interconnection layers UM1, UM2, UM3.

The substrate 10 may be bulk silicon or silicon-on-insulator (SOI). The substrate 100 may also be a silicon substrate. The substrate 10 may include, but is not limited to, silicon germanium, silicon germanium on insulator (SGOI), indium antimonide, lead telluride compounds, indium arsenide, indium phosphide, gallium arsenide, or gallium antimonide.

The circuit devices 11 may include transistors. The transistor may include a first gate electrode 11a disposed on the substrate 10, a first gate insulating layer 11b between the substrate 10 and the first gate electrode 11a, and a source region 11c and a drain region 11d provided in the substrate 10 on either side of the first gate electrode 11a. The circuit devices 11 may include peripheral circuitry for controlling the operation of the memory cell array. The peripheral circuitry may include, for example, but is not limited to, a row decoder, a page buffer circuit, control logic, and a voltage generator.

The MOS capacitor 12 may include a second gate electrode disposed on the substrate 10, an active region of the substrate 10 overlapping with the second gate electrode 12a, and a second gate insulating layer 12b between the active region and the second gate electrode 12a. One of the second gate electrode 12a and the active region may be connected to a power line, and the other may be connected to a ground line. In an embodiment, the MOS capacitor 12 can be used as a decoupling capacitor.

The lower dielectric layers 13a, 13b, 13c, 13d may include, for example, a first lower dielectric layer 13a, a second lower dielectric layer 13b, a third lower dielectric layer 13c, and a fourth lower dielectric layer 13d. The first, second, third, and fourth lower dielectric layers 13a, 13b, 13c, 13d may include at least one of, for example, a silicon oxide, a silicon nitride, and a silicon oxynitride.

The lower interconnection layers UM1, UM2, UM3, UM3 may include, for example, a first lower interconnection layer UM1, a second lower interconnection layer UM2, and a third lower interconnection layer UM3.

The first lower dielectric layer 13a may be disposed on the substrate 10, and may cover the circuit devices 11 and the MOS capacitor 12. The first lower interconnection layer UM1 may be disposed on the first lower dielectric layer 13a.

The second lower dielectric layer 13b may be disposed on the first lower dielectric layer 13a, and may cover the first lower interconnection layer UM1. The second lower interconnection layer UM2 may be disposed on the second lower dielectric layer 13b.

The third lower dielectric layer 13c may be disposed on the second lower dielectric layer 13b, and may cover the second lower interconnection layer UM2. The third lower interconnection layer UM3 may be disposed on the third lower dielectric layer 13c.

The fourth lower dielectric layer 13d may be disposed on the third lower dielectric layer 13c, and may cover the third lower interconnection layer UM3.

Although FIG. 1 illustrates the case of including three lower interconnection layers, it is not limited thereto. A semiconductor device according to various embodiments of the present disclosure may include at least one lower interconnection layer.

Each of the first lower interconnection layer UM1, the second lower interconnection layer UM2, and the third lower interconnection layer UM3 may include main decoupling capacitor first electrodes Pm and main decoupling capacitor second electrodes Gm disposed in the main decoupling capacitor region MDR. The main decoupling capacitor first electrodes Pm may be connected to a power line, and the main decoupling capacitor second electrodes Gm may be connected to a ground line.

On each of the first lower interconnection layer UM1, the second lower interconnection layer UM2, and the third lower interconnection layer UM3, the main decoupling capacitor first electrodes Pm and the main decoupling capacitor second electrodes Gm may be alternately disposed one by one.

The main decoupling capacitor first electrodes Pm of the first lower interconnection layer UM1, the main decoupling capacitor second electrodes Gm of the first lower interconnection layer UM1, and the second lower dielectric layer 13b between them may constitute a first main decoupling capacitor.

The main decoupling capacitor first electrodes Pm of the second lower interconnection layer UM2, the main decoupling capacitor second electrodes Gm of the second lower interconnection layer UM2, and the third lower dielectric layer 13c between them may constitute a second main decoupling capacitor.

The main decoupling capacitor first electrodes Pm of the third lower interconnection layer UM3, the main decoupling capacitor second electrodes Gm of the third lower interconnection layer UM3, and the fourth lower dielectric layer 13d between them may constitute a third main decoupling capacitor.

At least a part of the main decoupling capacitor first electrodes Pm of the first lower interconnection layer UM1 and at least a part of the main decoupling capacitor second electrodes Gm of the second lower interconnection layer UM2 may be vertically overlapping with each other. At least a part of the main decoupling capacitor second electrodes Gm of the first lower interconnection layer UM1 and at least a part of the main decoupling capacitor first electrodes Pm of the second lower interconnection layer UM2 may be vertically overlapping with each other.

At least a part of the main decoupling capacitor first electrodes Pm of the second lower interconnection layer UM2 and at least a part of the main decoupling capacitor second electrodes Gm of the third lower interconnection layer UM3 may be vertically overlapping with each other. At least a part of the main decoupling capacitor second electrodes Gm of the second lower interconnection layer UM2 and at least a part of the main decoupling capacitor first electrodes Pm of the third lower interconnection layer UM3 may be vertically overlapping with each other.

The main decoupling capacitor first electrodes Pm of the first lower interconnection layer UM1, the main decoupling capacitor second electrodes Gm of the second lower interconnection layer UM2, and the second lower dielectric layer 13b between them may constitute a fourth main decoupling capacitor.

The main decoupling capacitor second electrodes Gm of the first lower interconnection layer UM1, the main decoupling capacitor first electrodes Pm of the second lower interconnection layer UM2, and the second lower dielectric layer 13b between them may constitute a fifth main decoupling capacitor.

The main decoupling capacitor first electrodes Pm of the second lower interconnection layer UM2, the main decoupling capacitor second electrodes Gm of the third lower interconnection layer UM3, and the third lower dielectric layer 13c between them may constitute a sixth main decoupling capacitor.

The main decoupling capacitor second electrodes Gm of the second lower interconnection layer UM2, the main decoupling capacitor first electrodes Pm of the third lower interconnection layer UM3, and the third lower dielectric layer 13c between them may constitute a seventh main decoupling capacitor.

Each of the first lower interconnection layer UM1, the second lower interconnection layer UM2, and the third lower interconnection layer UM3 may include additional decoupling capacitor first electrodes Pa and additional decoupling capacitor second electrodes Ga disposed in the additional decoupling capacitor region ADR. The additional decoupling capacitor first electrodes Pa may be connected to a power line, and the additional decoupling capacitor second electrodes Ga may be connected to a ground line.

On each of the first lower interconnection layer UM1, the second lower interconnection layer UM2, and the third lower interconnection layer UM3, the additional decoupling capacitor first electrodes Pa and the additional decoupling capacitor second electrodes Ga may be alternately disposed one by one.

The additional decoupling capacitor first electrodes Pa of the first lower interconnection layer UM1, the additional decoupling capacitor second electrodes Ga of the first lower interconnection layer UM1, and the second lower dielectric layer 13b between them may constitute a first additional decoupling capacitor.

The additional decoupling capacitor first electrodes Pa of the second lower interconnection layer UM2, the additional decoupling capacitor second electrodes Ga of the second lower interconnection layer UM2, and the third lower dielectric layer 13c between them may constitute a second additional decoupling capacitor.

The additional decoupling capacitor first electrodes Pa of the third lower interconnection layer UM3, the additional decoupling capacitor second electrodes Ga of the third lower interconnection layer UM3, and the fourth lower dielectric layer 13d between them may constitute a third additional decoupling capacitor.

At least a part of the additional decoupling capacitor first electrodes Pa of the first lower interconnection layer UM1 and at least a part of the additional decoupling capacitor second electrodes Ga of the second lower interconnection layer UM2 may be vertically overlapping with each other. At least a part of the additional decoupling capacitor second electrodes Ga of the first lower interconnection layer UM1 and at least a part of the additional decoupling capacitor first electrodes Pa of the second lower interconnection layer UM2 may be vertically overlapping with each other.

At least a part of the additional decoupling capacitor first electrodes Pa of the second lower interconnection layer UM2 and at least a part of the additional decoupling capacitor second electrodes Ga of the third lower interconnection layer UM3 may be vertically overlapping with each other. At least a part of the additional decoupling capacitor second electrodes Ga of the second lower interconnection layer UM2 and at least a part of the additional decoupling capacitor first electrodes Pa of the third lower interconnection layer UM3 may be vertically overlapping with each other.

The additional decoupling capacitor first electrodes Pa of the first lower interconnection layer UM1, the additional decoupling capacitor second electrodes Ga of the second lower interconnection layer UM2, and the second lower dielectric layer 13b between them may constitute a fourth additional decoupling capacitor.

The additional decoupling capacitor second electrodes Ga of the first lower interconnection layer UM1, the additional decoupling capacitor first electrodes Pa of the second lower interconnection layer UM2, and the second lower dielectric layer 13b between them may constitute a fifth additional decoupling capacitor.

The additional decoupling capacitor first electrodes Pa of the second lower interconnection layer UM2, the additional decoupling capacitor second electrodes Ga of the third lower interconnection layer UM3, and the third lower dielectric layer 13c between them may constitute a sixth additional decoupling capacitor.

The additional decoupling capacitor second electrodes Ga of the second lower interconnection layer UM2, the additional decoupling capacitor first electrodes Pa of the third lower interconnection layer UM3, and the third lower dielectric layer 13c between them may constitute a seventh additional decoupling capacitor.

The upper structure 200 may include a source plate 20, a gate laminate 21, a plurality of cell plugs 22, upper dielectric layers 23a, 23b, 23c, and upper interconnection layers M1, M2.

The source plate 20 may be disposed on the second region R2 of the lower structure 100. The source plate 20 may include a doped semiconductor.

The gate laminate 21 may include a plurality of interlayer insulating layers 21a and a plurality of gate electrode layers 21b alternately stacked on the source plate 20. The gate electrode layers 21b may include a conductive material. For example, the gate electrode layers 21b may include tungsten (W). The interlayer insulating layer 21a may include silicon oxide. The gate electrode layers 21b may include word lines. The gate electrode layer 21b may further include at least one source select line and at least one drain select line.

The cell plugs 22 may extend vertically through the gate laminate 21 and into the source plate 20. Each of the cell plugs 22 may include a channel layer 22a and a cell gate insulating layer 22b. The cell gate insulating layer 22b may have a straw or cylinder shell shape that wraps around the outer wall of the channel layer 22a. The cell gate insulation layer 22b can include a tunnel insulating layer, a charge storage layer, and a blocking layer formed sequentially from the outer wall of the channel layer 22a. In some embodiments, the cell gate insulating layer 22b may have an oxide-nitride-oxide (ONO) laminated structure in which an oxide layer, a nitride layer and an oxide layer are sequentially laminated. The memory cells may be formed where the word lines wrap around the cell plugs 22. A source select transistor may be formed where the source select lines wrap around the cell plugs 22. A drain select transistor may be formed where the drain select lines wrap around the cell plugs 22. The drain select transistor, the plurality of memory cells, and the source select transistor disposed along one cell plug 22 may comprise a cell string. A plurality of cell strings corresponding to the plurality of cell plugs 22 may be provided in the second region R2 of the upper structure 200. The plurality of cell strings may comprise a memory cell array.

The upper dielectric layers 23a, 23b, 23c can include, for example, a first upper dielectric layer 23a, a second upper dielectric layer 23b, and a third upper dielectric layer 23c. The first, second, and third upper dielectric layers 23a, 23b, 23c may include at least one of, for example, silicon oxide, silicon nitride, and silicon oxynitride.

The first upper dielectric layer 23a may be disposed on the fourth lower dielectric layer 13d of the lower structure 100, and may cover the top surface and sides of the source plate 20, the top surface and sides of the gate laminate 21, and the sides of the cell plugs 22. The second upper dielectric layer 23b is disposed on the first upper dielectric layer 23a, and may cover the top surface of the cell plugs 22.

The first upper interconnection layer M1 may be disposed on the second upper dielectric layer 23b. The first upper interconnection layer M1 may include a bit line BL and a third electrode 24a.

At the bottom of the bit line BL, a bit line contact 25 may be disposed that extends through the second upper dielectric layer 23b and to the cell plug 22. The bit line BL may be connected to the cell plug 22 via the bit line contact 25.

The third electrode 24a may be disposed to vertically overlap with the first external connection pad 26. Although FIG. 1 illustrates only one third electrode 24a, the first upper interconnection layer M1 may include a plurality of third electrodes 24a disposed in a region vertically overlapping with the first external connection pad 26.

The third upper dielectric layer 23c may be disposed on the second upper dielectric layer 23b to cover the first upper interconnection layer M1. The bit line BL and the third electrode 24a may be covered by the third upper dielectric layer 23c. The second upper interconnection layer M2 may be disposed on the third upper dielectric layer 23c. The second upper interconnection layer M2 may include the first external connection pad 26.

When the first external connection pad 26 is a power pad, the third electrode 24a may be connected to a ground line. Accordingly, a decoupling capacitor including the third electrode 24a, the first external connection pad 26, and the third upper dielectric layer 23c between them may be constituted.

On the other hand, when the first external connection pad 26 is a ground pad, the third electrode 24a may be connected to a power line. Accordingly, a decoupling capacitor including the third electrode 24a, the first external connection pad 26, and the third upper dielectric layer 23c between them may be constituted.

A protective layer 27 may be disposed on the third upper dielectric layer 23c. The protective layer 27 may have an open region OP exposing the first external connection pad 26.

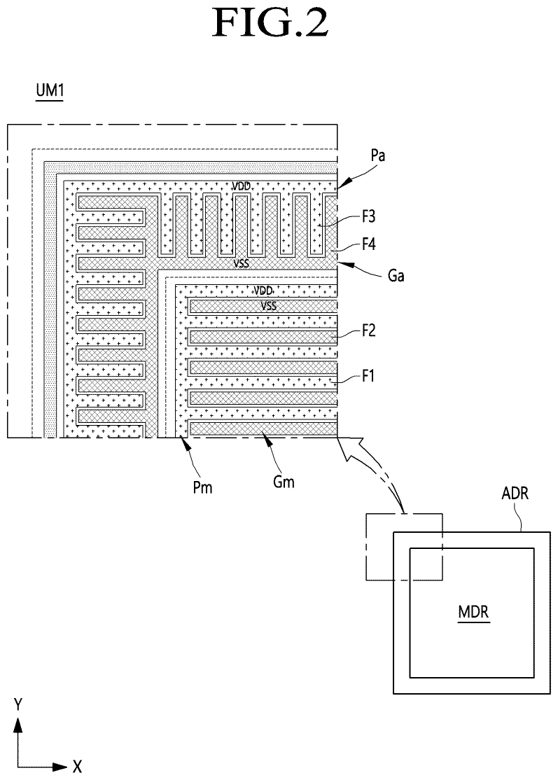

FIG. 2 is a plan view illustrating the main decoupling capacitor region and the additional decoupling capacitor region of the first lower interconnection layer of FIG. 1.

Referring to FIG. 2, the additional decoupling capacitor region ADR may surround the main decoupling capacitor region MDR in X-Y plane. The main decoupling capacitor region MDR may be positioned within the interior surrounded by the additional decoupling capacitor region ADR in X-Y plane.

The main decoupling capacitor first electrode Pm and the main decoupling capacitor second electrode Gm of the first lower interconnection layer UM1 may have a finger structure. Specifically, the main decoupling capacitor first electrode Pm may include a plurality of first fingers F1, and the main decoupling capacitor second electrode Gm may include a plurality of second fingers F2. In an embodiment, the first finger F1 may provide an operating voltage VDD and the second finger F2 may provide a ground voltage VSS.

The first fingers F1 and the second fingers F2 may be disposed alternately in X-Y plane and may be engaged with each other. As the first fingers F1 and the second fingers F2 are engaged with each other, the overlap area between the main decoupling capacitor first electrode Pm, and the main decoupling capacitor second electrode Gm may increase. Thus, an embodiment can provide a high capacity main decoupling capacitor.

Similar to the main decoupling capacitor first electrode Pm and the main decoupling capacitor second electrode Gm of the first lower interconnection layer UM1, the additional decoupling capacitor first electrode Pa and the additional decoupling capacitor second electrode Ga of the first lower interconnection layer UM1 may also have a finger structure. Specifically, the additional decoupling capacitor first electrode Pa may include a plurality of third fingers F3, and the additional decoupling capacitor second electrode Ga may include a plurality of fourth fingers F4. In an embodiment, the third finger F3 may provide an operating voltage VDD and the fourth finger F4 may provide a ground voltage VSS.

The third fingers F3 and the fourth fingers F4 may be disposed alternately in X-Y plane and may be engaged with each other. Since the third fingers F3 and the fourth fingers F4 are engaged with each other, the overlap area between the additional decoupling capacitor first electrode Pa and the additional decoupling capacitor second electrode Ga may increase. Thus, an embodiment can provide a high capacity additional decoupling capacitor.

Although not shown, the main decoupling capacitor first electrode Pm and the main decoupling capacitor second electrode Gm of the second lower interconnection layer (UM2 in FIG. 1), and the main decoupling capacitor first electrode Pm and the main decoupling capacitor second electrode Gm of the third lower interconnection layer (UM3 in FIG. 1) may have similar shapes to the main decoupling capacitor first electrode Pm and the main decoupling capacitor second electrode Gm of the first lower interconnection layer (UM1 of FIG. 1) shown in FIG. 2.

The additional decoupling capacitor first electrode Pa and the additional decoupling capacitor second electrode Ga of the second lower interconnection layer (UM2 in FIG. 1), and the additional decoupling capacitor first electrode Pa and the additional decoupling capacitor second electrode Ga of the third lower interconnection layer (UM3 in FIG. 1), may have similar shapes to the additional decoupling capacitor first electrode Pa and the additional decoupling capacitor second electrode Ga of the first lower interconnection layer (UM1 of FIG. 1) shown in FIG. 2.

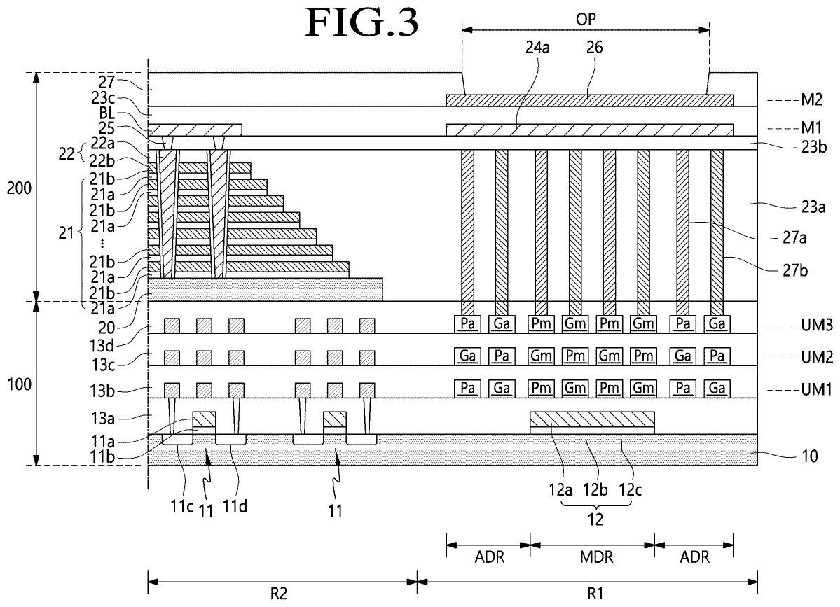

FIG. 3 is a cross-sectional view of a semiconductor device according to embodiments of the present disclosure.

Referring to FIG. 3, a semiconductor device according to embodiments of the present disclosure may include first vertical vias 27a and second vertical vias 27b disposed between the first upper interconnection layer M1 and the third lower interconnection layer UM3.

The first vertical vias 27a and the second vertical vias 27b may vertically penetrate the first upper dielectric layer 23a in the region vertically overlapping with the first external connection pad 26. The first vertical vias 27a and the second vertical vias 27b may be disposed alternately one after the other.

The first vertical vias 27a may be connected to a power voltage line, and the second vertical vias 27b may be connected to a ground line.

For example, each of the first vertical vias 27a may vertically penetrate the first upper dielectric layer 23a and the fourth lower dielectric layer 13d to be connected to one of the main decoupling capacitor first electrodes Pm and the additional decoupling capacitor first electrodes Pa, and may be connected to the power line through one of the main decoupling capacitor first electrodes Pm and the additional decoupling capacitor first electrodes Pa. Each of the second vertical vias 27b may vertically penetrate the first upper dielectric layer 23a and the fourth lower dielectric layer 13d to be connected to one of the main decoupling capacitor second electrodes Gm and the additional decoupling capacitor second electrodes Ga, and may be connected to a ground line through one of the main decoupling capacitor second electrodes Gm and the additional decoupling capacitor second electrodes Ga.

The first vertical vias 27a and the second vertical vias 27b, and the first upper dielectric layer 23a and the fourth lower dielectric layer 13d between them, may constitute a decoupling capacitor. The first vertical vias 27a constitute a first electrode of the decoupling capacitor. The second vertical vias 27b constitute a second electrode of the decoupling capacitor. The first upper dielectric layer 23a and the fourth lower dielectric layer 13d between the first vertical vias 27a and the second vertical vias 27b constitute a dielectric layer of the decoupling capacitor.

In an embodiment, by increasing the number of stacking of the gate electrode layers 21b to increase the integration, the thickness of the first upper dielectric layer 23a disposed in the first region R1 is increased. In accordance with various embodiments of the present disclosure, the capacity of the decoupling capacitor can be increased by forming first and second vertical vias 27a, 27b through the first upper dielectric layer 23a in the first region R1, and constituting a decoupling capacitor using the first and second vertical vias 27a, 27b.

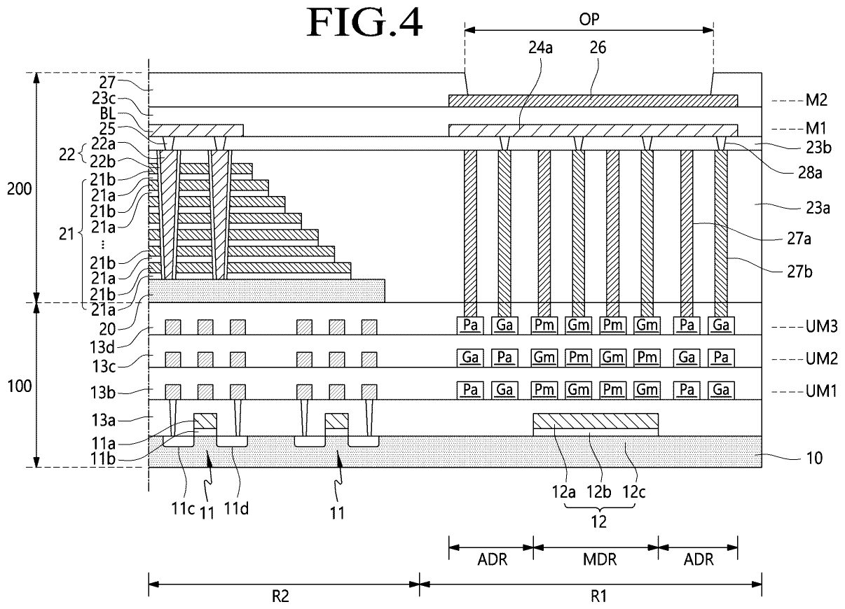

FIG. 4 is a cross-sectional view illustrating a semiconductor device according to various embodiments of the present disclosure.

Referring to FIG. 4, a semiconductor device according to embodiments of the present disclosure may include first vertical contacts 28a connecting a third electrode 24a of the first top interconnection layer M1 with a second vertical vias 27b.

The first vertical contacts 28a may be connected to the second vertical vias 27b by vertically penetrating the second upper dielectric layer 23b from the bottom of the third electrode 24a. The third electrode 24a may be connected to the second vertical vias 27b via the first vertical contacts 28a.

FIG. 4 illustrates a case where the first external connection pad 26 is a power pad, where the first vertical contacts 28a connect the third electrode 24a and the second vertical vias 27b, but is not limited to. If the first external connection pad 26 is a ground pad, the first vertical contacts 28a may connect the third electrode 24a and the first vertical vias 27a.

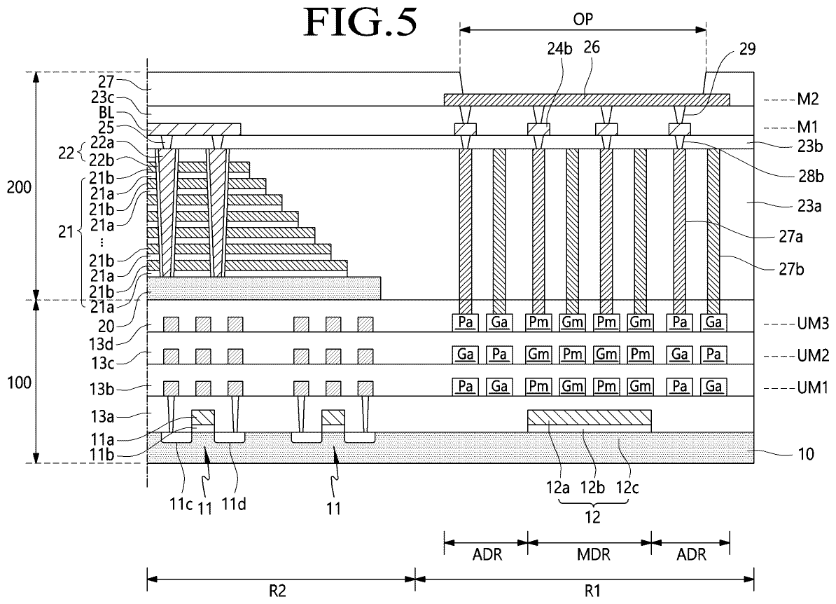

FIG. 5 is a cross-sectional view illustrating a semiconductor device according to various embodiments of the present disclosure.

Referring to FIG. 5, a semiconductor device according to various embodiments of the present disclosure may include a second vertical contacts 28b connecting the third electrode 24b to the first vertical vias 27a, and third vertical contacts 29 connecting the first external connection pad 26 to the third electrode 24b.

A second vertical contact 28b may be connected to the first vertical via 27a by vertically penetrating the second upper dielectric layer 23b from the bottom of the third electrode 24b. A third vertical contact 29 may be connected to the third electrode 24b by penetrating the third upper dielectric layer 23c from the bottom of the first external connection pad 26. The first vertical via 27a may be connected to the first external connection pad 26 via the second vertical contact 28b, the third electrode 24b, and the third vertical contact 29.

In an embodiment, the second vertical contact 28b, the third electrode 24b, and the third vertical contact 29 may be vertically aligned with each other. In an embodiment, because the second vertical contact 28b, the third electrode 24b, and the third vertical contact 29 connecting the first vertical via 27a and the first external connection pad 26 are vertically aligned, the electrical path connecting the first vertical via 27a and the first external connection pad 26 may have a length corresponding to a straight line distance between the first vertical via 27a and the first external connection pad 26. Therefore, in an embodiment, by minimizing the length of the electrical path between the decoupling capacitor including the first vertical via 27a and the first external connection pad 26, the noise cancellation effect by the decoupling capacitor can be enhanced.

The above description is merely an example of a description of the technical ideas of the present disclosure, and various modifications and variations will be apparent to one having ordinary skill in the art to which the present disclosure belongs without departing from the essential features of the present disclosure. Further, the embodiments disclosed in the present disclosure are intended to illustrate and not to limit the technical ideas of the present disclosure, and the scope of the technical ideas of the present disclosure is not intended to be limited by these embodiments.

What is claimed is:

1. A semiconductor device comprising:
a substrate;
at least one lower interconnection layer disposed on the substrate;
a first upper interconnection layer on the at least one lower interconnection layer;
a second upper interconnection layer on the first upper interconnection layer;
an external connection pad, the second upper interconnection layer including the external connection pad; and
a metal oxide semiconductor (MOS) capacitor disposed on the substrate to be vertically overlapping with the external connection pad,
wherein the at least one lower interconnection layer comprises:
a main decoupling capacitor region vertically overlapping with the MOS capacitor; and
an additional decoupling capacitor region surrounding the main decoupling capacitor region.

2. The semiconductor device of claim 1,
wherein the at least one lower interconnection layer comprising:
main decoupling capacitor first electrodes disposed in the main decoupling capacitor region;
main decoupling capacitor second electrodes disposed in the main decoupling capacitor region;
additional decoupling capacitor first electrodes disposed in the additional decoupling capacitor region; and
additional decoupling capacitor second electrodes disposed in the additional decoupling capacitor region,
wherein the main decoupling capacitor first electrodes and the additional decoupling capacitor first electrodes are connected to a power line, and the main decoupling capacitor second electrodes and the additional decoupling capacitor second electrodes are connected to a ground line.

3. The semiconductor device of claim 2,
wherein each of the additional decoupling capacitor first electrodes and the additional decoupling capacitor second electrodes comprises a plurality of fingers,
wherein the at least one lower interconnection layer comprises a first lower interconnection layer, and
wherein the fingers of the additional decoupling capacitor first electrodes and the fingers of the additional decoupling capacitor second electrodes are disposed alternately and are engaged each other in the first lower interconnection layer.

4. The semiconductor device of claim 2,
wherein the at least one lower interconnection layer comprises a first lower interconnection layer, and a second lower interconnection layer on the first lower interconnection layer,
wherein at least a part of the additional decoupling capacitor first electrode of the first lower interconnection layer and at least a part of the additional decoupling capacitor second electrode of the second lower interconnection layer are vertically overlapping with each other
wherein at least a part of the additional decoupling capacitor second electrode of the first lower interconnection layer and at least a part of the additional decoupling capacitor first electrodes of the second lower interconnection layer are vertically overlapping with each other.

5. The semiconductor device of claim 2, further comprising:
a third electrode disposed on the first upper interconnection layer and vertically overlapping with the external connection pad; and
a decoupling capacitor comprising the external connection pad, the third electrode, and a dielectric layer between the external connection pad and the third electrode.

6. The semiconductor device of claim 5, wherein the external connection pad is a power pad and the third electrode is connected to a ground line.

7. The semiconductor device of claim 5, wherein the external connection pad is a ground pad and the third electrode is connected to a power line.

8. The semiconductor device of claim 1, wherein the additional decoupling capacitor region is vertically overlapping with the external connection pad and vertically non-overlapping with the MOS capacitor.

9. The semiconductor device of claim 1, wherein the additional decoupling capacitor region surrounds the periphery of the main decoupling capacitor region.

10. A semiconductor device comprising:
a peripheral structure comprising a substrate having a first region and a second region defined thereon, circuit devices disposed on the substrate, and a lower interconnection layer disposed on the circuit devices;
a cell structure comprising a memory cell array disposed on the second region of the peripheral structure, a first upper interconnection layer on the memory cell array, a second upper interconnection layer on the first upper interconnection layer, and an external connection pad disposed in the first region and the second upper interconnection layer including the external connection pad;
a first vertical via and a second vertical via vertically overlapping with the external connection pad and extending vertically between the lower interconnection layer and the first upper interconnection layer; and
a first decoupling capacitor comprising the first vertical via, the second vertical via, and a dielectric layer between the first vertical via and the second vertical via.

11. The semiconductor device of claim 10, wherein the first vertical via is connected to a power line, and the second vertical via is connected to a ground line.

12. The semiconductor device of claim 10,
wherein the lower interconnection layer comprises:
a main decoupling capacitor region vertically overlapping with a central region of the external connection pad; and
an additional decoupling capacitor region vertically overlapping with an edge region of the external connection pad.

13. The semiconductor device of claim 12,
wherein the lower interconnection layer comprises:
main decoupling capacitor first electrodes disposed in the main decoupling capacitor region and connected to a power line;
main decoupling capacitor second electrodes disposed in the main decoupling capacitor region and connected to a ground line;
additional decoupling capacitor first electrodes disposed in the additional decoupling capacitor region and connected to a power line;
additional decoupling capacitor second electrodes disposed in the additional decoupling capacitor region and connected to a ground line.

14. The semiconductor device of claim 13,
wherein the first vertical via is connected to one of the main decoupling capacitor first electrode and the additional decoupling capacitor first electrode, and
wherein the second vertical via is connected to one of the main decoupling capacitor second electrode and the additional decoupling capacitor second electrode.

15. A semiconductor device, comprising:
a peripheral structure comprising a substrate having a first region and a second region defined thereon, a metal oxide semiconductor (MOS) capacitor disposed on the first region of the substrate, a lower dielectric layer covering the MOS capacitor, and a lower interconnection layer disposed in the lower dielectric layer;
a cell structure comprising a source plate disposed on the second region of the peripheral structure, a gate laminate comprising a plurality of gate electrode layers and a plurality of interlayer insulating layers alternately stacked on the source plate, a first upper dielectric layer covering the source plate and the gate laminate, a second upper dielectric layer on the first upper dielectric layer, a first upper interconnection layer on the second upper dielectric layer, a third upper dielectric layer covering the first upper interconnection layer, a second upper interconnection layer on the third upper dielectric layer; and an external connection pad disposed in the first region, the external connection pad included in the second upper interconnection layer;
a first vertical via and a second vertical via vertically overlapping with the external connection pad and vertically penetrating the first upper dielectric layer; and
a first decoupling capacitor comprising the first vertical via, the second vertical via, and the first upper dielectric layer between the first vertical via and the second vertical via.

16. The semiconductor device of claim 15,
wherein the lower interconnection layer comprises:
main decoupling capacitor first electrodes disposed in a main decoupling capacitor region vertically overlapping with the MOS capacitor;
main decoupling capacitor second electrodes disposed in the main decoupling capacitor region;
additional decoupling capacitor first electrodes disposed in an additional decoupling capacitor region surrounding the main decoupling capacitor region; and
additional decoupling capacitor second electrodes disposed in the additional decoupling capacitor region, and
wherein the main decoupling capacitor first electrodes and the additional decoupling capacitor first electrodes are connected to a power line, and the main decoupling capacitor second electrodes and the additional decoupling capacitor second electrodes are connected to a ground line.

17. The semiconductor device of claim 15, further comprising:
a third electrode disposed on the first upper interconnection layer and vertically overlapping with the external connection pad; and
a second decoupling capacitor comprising the external connection pad, the third electrode, and the third upper dielectric layer between the external connection pad and the third electrode.

18. The semiconductor device of claim 17, further comprising a vertical contact penetrating the second upper dielectric layer and connecting one of the first vertical via and the second vertical via to the third electrode.

19. The semiconductor device of claim 17, further comprising:
a first vertical contact vertically penetrating the second upper dielectric layer and connecting one of the first vertical via and the second vertical via to the third electrode; and
a second vertical contact vertically penetrating the third upper dielectric layer and connecting the third electrode to the external connection pad.

20. The semiconductor device of claim 19, wherein the first vertical contact, the third electrode, and the second vertical contact are vertically aligned with each other.
